(19) United States
(12) Patent Application Publication
(10) Pub. No.: US 2002/0139306 A1
(43) Pub. Date: Oct. 3, 2002

(54) Locator for a material sheet

(75) Inventors: Tsung-Lin Lu, Tainan Hsien (TW); Ta-Shuang Kuan, Hsinchu Hsien (TW); Kuen-Jian Chen, Hsinchu Hsien (TW)

Correspondence Address: Dougherty & Troxell, ONE SKYLINE PLACE, SUITE 1404, 5202 LEESBURG PIKE, FALLS CHURCH, VA, 22041, US

(73) Assignee: Unipac Optoelectronics Corporation

(21) Appl. No.: 09/867,408

(22) Filed: May 31, 2001

(30) Foreign Application Priority Data
Apr. 2, 2001 (TW) 90205048

(51) Int. Cl. B05C 13/00; B05C 21/00; C23C 16/00

(52) U.S. Cl. 118/728; 118/500

(57) ABSTRACT

A locator for a material sheet comprises a frame with a homogeneous cross section, and a susceptor. The frame at the left, the right, the front, and the rear sides thereof surrounds with an inner wall. The distance between the left and the right sides of the inner wall and the distance between the front and the rear sides thereof are corresponding to the size of the upward projection of the susceptor. The upper end of the inner wall extends outward a horizontal support surface. The distance between the left and the right sides of the support surface and the distance between the front and the rear sides of the support surface are corresponding to the size of the sheet. An upward slant surface extends outward from the support surface. The sheet can slide downward along the slant surface to cover the susceptor while the sheet is laid down from the top of the locator.

### BACKGROUND OF THE INVENTION

1. Field of The Invention

The present invention relates to a locator for a material sheet, and particularly to a locator for confining a distance between two end parts of a sheet effectively.

2. Description of Related Art

Conventionally, locating the position of material sheet such as a sheet of glass, a sheet of chip, or the like during the operation of plasma enhanced chemical vapor deposition as shown in FIG. 1 is performed by way of a susceptor with a jutting out central projection part being laid down the material sheet for film deposition and a shadow frame being placed surrounding the projection part for positioning the material sheet in place. Meanwhile, the preceding locator can prevent the process gases from flowing disorderly and avoid arcing such that it is possible for the susceptor to keep off being damaged.

Although the preceding way of locating the sheet material is able to offer the basic function of film deposition, there is a defect that the material sheet at the periphery thereof may be not deposited due to being shaded by the shadow frame and it results in a less available area on the material sheet.

Thereby, in order to increase the available area, to reduce the width of the shadow frame is a way usually done to solve the problem. It is known that the width of the shadow frame is around 3 mm under a condition of optimum effective deposition area and it is a challenge naturally for the so small amount of width to carry out the positioning job. Hence, it often to occur a phenomenon of positional deviation that the smooth material sheet is apart from the area of the shadow frame as shown in FIG. 2. The problem with regard to the positional deviation has been left there for years and it is a bottleneck needed to overcome.

### SUMMARY OF THE INVENTION

An object of present invention is to provide a locator for a material sheet, in which a support frame is disposed surrounding the central projection part of the susceptor instead of the shadow frame to position the material sheet such as a sheet of glass, chip or the like effectively with an increased plated area on the material sheet.

### BRIEF DESCRIPTION OF THE DRAWINGS

The present invention can be more fully understood by referring to the following description and accompanying drawings, in which:

FIG. 1 is a sectional view illustrating a conventional way for locating a material sheet during film deposition;

FIG. 2 is a sectional view illustrating the material sheet being in a state of being located improperly by way of conventional mode;

FIG. 3 is a sectional view illustrating the material sheet being located by way of locating frame of the present invention; and

FIG. 4 is a perspective view of another embodiment of the present invention.

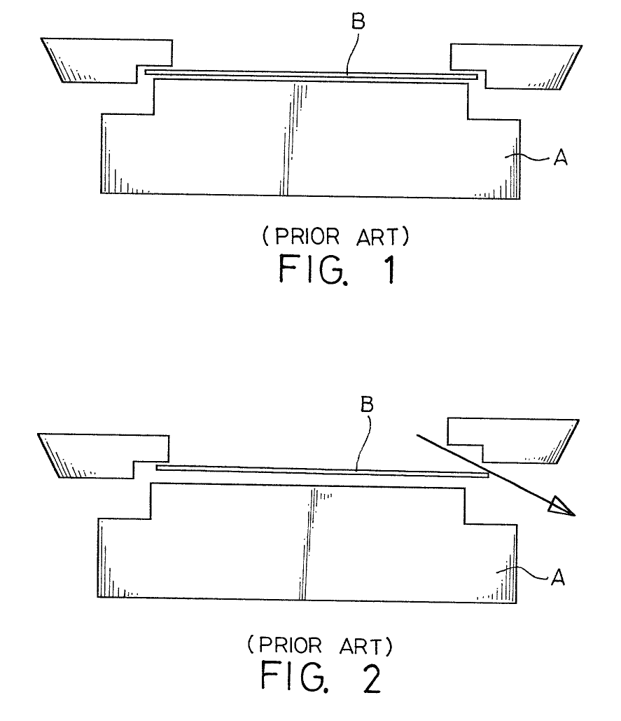

### DETAILED DESCRIPTION OF THE PREFERRED EMBODIMENTS

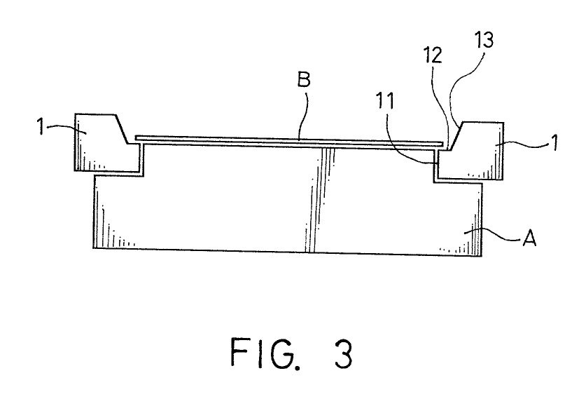

Referring to FIG. 3, a mode of locating disclosed in the present invention is by way of supporting instead of the mode of shading frequently used conventionally. A support frame 1 is provided in the first embodiment of present invention.

The support frame 1 is solid with a homogenous cross section with an inner wall 11 and a distance between the left and right sides of inner wall 11 thereof is corresponding to the length of an upward projection part on the susceptor A so that it is possible to enclose the upward projection or to be astride on the susceptor A. The height of each inner wall 11 is corresponding to the height of the upward projection such that the material sheet can be supported by the support frame 1 while the material sheet is placed on the susceptor A. But, it is noted that there is no restriction about the height of the inner wall 11 and regardless the preceding height is corresponding to the upward projection part of the susceptor A, it can be higher than or less than the upward projection part on the susceptor A depending on the actual need while in use.

The inner wall 11 at the upper end thereof extends outward horizontally to form a flat frame surface 12. In order to receive the sheet B, the outer most distance between the left and the right sides of the frame surface 12 is corresponding to the width of the sheet B, and the outer most distance between the front and the rear sides thereof is corresponding to length of sheet B. As it has been mentioned in the preceding description, the outer most distances can be adjusted to be greater than the width or the length of the sheet B respectively.

Besides, the frame surface 12 has an upward slant surface 13 extending outward to facilitate the sheet B being located properly. The slant surface 13 allow the sheet B slides downward to the suspector A while the sheet B is laid down from the top of the locator of the present invention.

Referring to FIG. 3 again, due to the spread area of process gases being greater than the sheet of glass B in practice, the entire upper surface on the sheet of glass B can be deposited with a film. The suspector A is covered by the sheet B completely so that there is no any harm to the suspector A and the available deposited area can be increased effectively with uniformly deposited film. In addition, the sheet B is located in place completely such that the disordered flow of the process gases is resisted to prevent from the phenomenon of arcing and damaged the suspector A. The preceding advantages of the present invention are not possible for the conventional locating device to reach in case of film deposition.

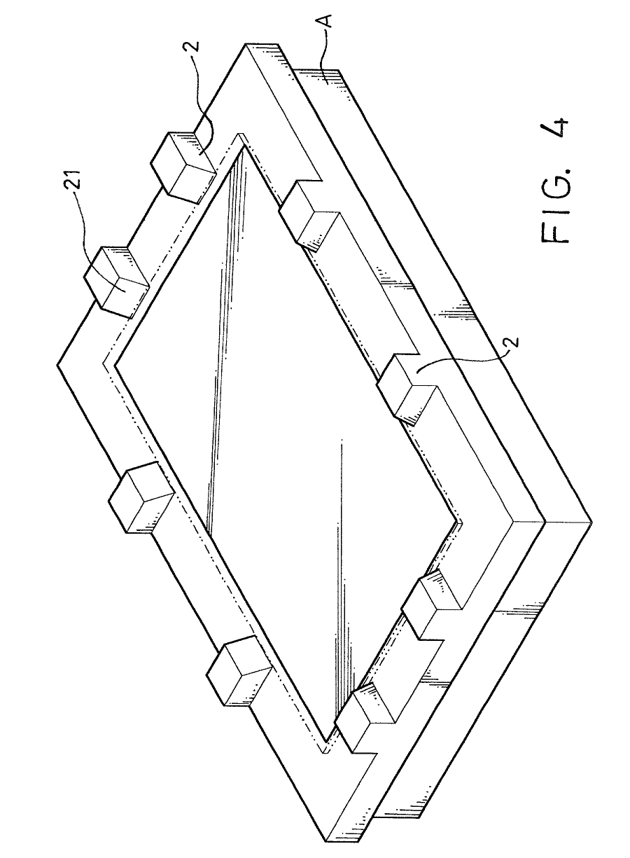

Referring to FIG. 4, another embodiment of the present invention is illustrated and basically a plain flat frame is provided instead of the support frame 1 shown in FIG. 3. A plurality of support pieces 2 project upward from the upper surface of the flat frame and the support pieces 2 are disposed to space apart from one another. Each one of the support pieces 2 provides a slant surface 21 can perform a locating job without shadow as the support frame 1 shown in FIG. 3 does. The respective support piece 2 as shown in FIG. 4 is solid with the slant surface 21, but this is not to restrict the configuration thereof, that is, it is possible for the configuration of each support piece 2 to be revised in accordance with the actual need. For instance, it can be a configuration of triangular post or pyramid with slant surface jutting out on the upper surface or the top area on each support piece 2 shown in FIG. 4 can be reduced.

While the invention has been described with reference to preferred embodiments thereof, it is to be understood that modifications or variations may be easily made without departing from the spirit of this invention, which is defined by the appended claims.

What is claimed is:

1. A locator for a material sheet comprising
a frame with a left, a right, a front, and a rear sides, having a homogeneous cross section surrounding the four sides, providing an inner wall surrounding the four sides with a first distance between the left and the right sides of the inner wall and a second distance between the front and the rear sides thereof, an upper end of said inner wall extending outward a horizontal support surface surrounding the four sides, a third distance between the left and the right sides of the support surface and a fourth distance between the front and the rear sides of the support surface being corresponding to a size of said sheet, and an upward slant surface extending outward from the support surface; and
a susceptor, providing an upward projection part with a size corresponding to the first distance and second distance;
Whereby, the sheet can slide downward along the slant surface to cover the susceptor while the sheet is laid down from the top of the locator.

2. The locator for a material sheet according to claim 1, wherein the inner wall provides a height corresponding to a height of the upward projection on the susceptor.

3. The locator for a material sheet according to claim 1, wherein the sheet is made of glass.

4. The locator for a material sheet according to claim 1, wherein the sheet is a sheet of chip.

5. A locator for a material sheet comprising
a frame with an upper flat surface;
a plurality of projection pieces, being disposed on the upper surface and spacing apart one another, each one of the projection pieces being solid with a inner slant surface;
whereby, the sheet can be located by way of the respective inner surface.

6. The locator for a material sheet according to claim 5, wherein the sheet is made of glass.

7. The locator for a material sheet according to claim 5, wherein the sheet is a sheet of chip.
